(19) United States
(12) Patent Application Publication
(10) Pub. No.: US 2023/0134698 A1
(43) Pub. Date: May 4, 2023

(54) APPARATUS AND METHOD TO CONTROL THRESHOLD VOLTAGE AND GATE LEAKAGE CURRENT FOR GAN-BASED SEMICONDUCTOR DEVICES

(71) Applicant: Texas Instruments Incorporated, Dallas, TX (US)

(72) Inventors: Jungwoo Joh, Allen, TX (US); Sameer Prakash Pendharkar, Allen, TX (US); Qhalid RS Fareed, Plano, TX (US); Chang Soo Suh, Allen, TX (US)

(21) Appl. No.: 17/514,550

(22) Filed: Oct. 29, 2021

(51) Int. Cl. H01L 29/778; H01L 29/205; H01L 29/66; H01L 29/20

(52) U.S. Cl. CPC H01L 29/7786; H01L 29/205; H01L 29/66462; H01L 29/2003

(57) ABSTRACT

A gallium nitride (“GaN”)-based semiconductor device, and method of forming the same. In one example, the semiconductor device includes a channel layer including GaN, and a barrier layer of a first III-N material over the channel layer. The semiconductor device also includes a cap layer of a second III-N material including indium over the barrier layer, wherein the cap layer may have the effect of modifying a threshold voltage and gate leakage current of the semiconductor device.

### TECHNICAL FIELD

The present disclosure relates to the field of semiconductor devices and, more particularly, to an apparatus and method to control a threshold voltage and gate leakage current for a gallium nitride (“GaN”)-based semiconductor device.

### BACKGROUND

Gallium nitride (“GaN”)-based semiconductor devices deliver some enhanced characteristics compared to silicon-based semiconductor devices. The GaN-based semiconductor devices have faster-switching speeds and advantageous reverse-recovery performance, which is beneficial for low-loss and high-efficiency performance. However, control of the threshold voltage and gate leakage current, particularly for enhancement mode (“E-mode”) devices, is a challenge for GaN-based semiconductor devices.

A p-doped gallium nitride (“p-GaN”)-based gate structure is prone to high gate leakage current. The p-GaN-based gate structure typically includes p-GaN or p-doped aluminum gallium nitride (“p-AlGaN”) layer over a barrier layer, which does not enhance the threshold voltage of the GaN-based semiconductor device beyond a certain level. Accordingly, what is needed in the art is an apparatus and method to control a threshold voltage and gate leakage current for a GaN-based semiconductor device.

### SUMMARY

These and other problems are generally solved or their effects reduced, and technical advantages are generally achieved, by advantageous examples of the present disclosure which includes a gallium nitride (“GaN”)-based semiconductor device, and method of forming the same. In one example, the semiconductor device includes a channel layer including GaN, and a barrier layer of a first III-N material over the channel layer. The semiconductor device also includes a cap layer of a second III-N material including indium over the barrier layer, wherein the cap layer may have the effect of modifying a threshold voltage and gate leakage current of the semiconductor device.

The foregoing has outlined rather broadly the features and technical advantages of the present disclosure in order that the detailed description of the disclosure that follows may be better understood. Additional features and advantages of the disclosure will be described hereinafter which form the subject of the claims of the disclosure. It should be appreciated that the specific examples disclosed may be readily utilized as a basis for modifying or designing other structures or processes for carrying out the same purposes of the present disclosure. It should also be realized that such equivalent constructions do not depart from the spirit and scope of the disclosure as set forth in the appended claims.

### BRIEF DESCRIPTION OF THE DRAWINGS

For a more complete understanding of the present invention, reference is now made to the following descriptions taken in conjunction with the accompanying drawings, in which:

FIGS. 1 to 6 illustrate cross-sectional views of a method of forming a gallium nitride (“GaN”)-based semiconductor device;

FIGS. 7A to 7E illustrate block diagrams of example materials for a channel layer, barrier layer and a cap layer of a gallium nitride (“GaN”)-based semiconductor device;

FIG. 8 illustrates an energy band diagram for a p-doped gallium nitride (“p-GaN”)-based semiconductor device; and

FIG. 9 illustrates an energy band diagram for a gallium nitride (“GaN”)-based semiconductor device.

Corresponding numerals and symbols in the different figures generally refer to corresponding parts unless otherwise indicated, and may not be described again in the interest of brevity after the first instance. The FIGUREs are drawn to illustrate the relevant aspects of exemplary embodiments.

### DETAILED DESCRIPTION

The making and using of the examples are discussed in detail below. It should be appreciated, however, that the present disclosure provides many applicable concepts that can be embodied in a wide variety of specific contexts. The specific examples discussed are merely illustrative of specific ways to make and use examples consistent with the disclosure, and do not limit the scope of the disclosure.

The present disclosure will be described with respect to examples in a specific context, namely, a gallium nitride (“GaN”)-based semiconductor device, and method of forming the same. The principles of the present disclosure, however, may also be applied to similar types of semiconductor devices that may benefit from control of a threshold voltage and gate leakage current therefor.

For a better understanding of gallium nitride (“GaN”)-based semiconductor devices, see U.S. Pat. No. 11,049,960 entitled “Gallium Nitride (GaN) Based Transistor with Multiple P—GaN Blocks,” issued Jun. 29, 2021 (“the '960 patent”), by Suh, et al. and U.S. Patent Publication No. 2016/0293596 entitled “Normally Off III-Nitride Transistor,” published Oct. 6, 2016, by Fareed, et al., which are incorporated herein by reference in their entireties.

As introduced herein, an additional negative charge is provided in the GaN-based semiconductor device structure to make the threshold voltage more positive through polarization engineering. Using a narrower bandgap material such as indium gallium nitride, the additional band offset can also reduce gate leakage current. This method breaks a fundamental trade-off between drain-to-source on resistance (“Rdson”) versus threshold voltage (“Vt”) as well as gate leakage current (“IG”) versus maximum drain current (“Idmax”). Flexibility is thereby provided to tune the threshold voltage without compromising gate current or device on-resistance.

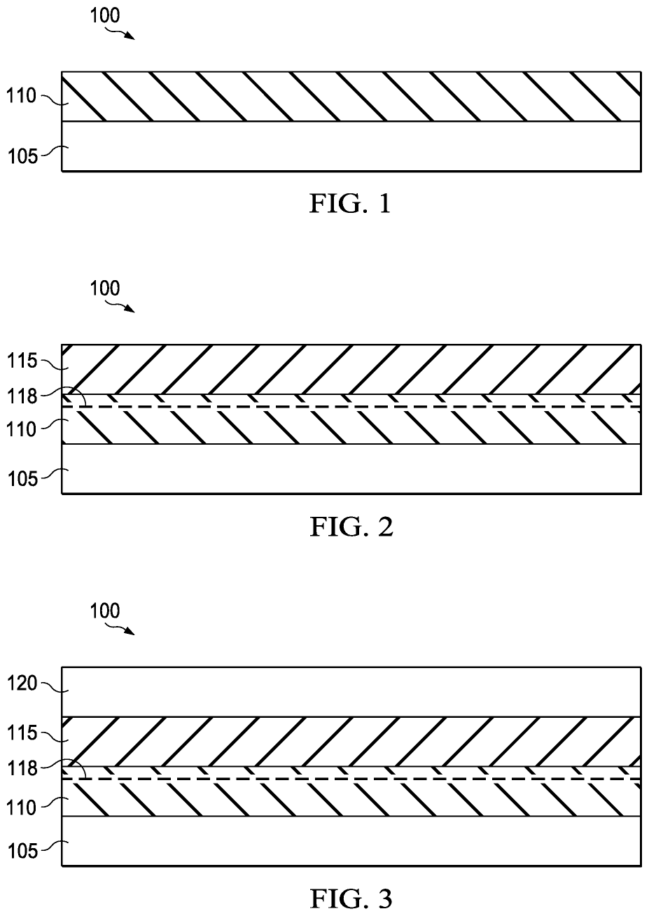

Referring initially to FIGS. 1 to 6, illustrated are cross-sectional views of a method of forming a semiconductor device 100. The semiconductor device 100 provides improved control of threshold voltage and gate leakage current. In this example, the semiconductor device 100 includes an enhancement mode gallium nitride (“GaN”) field-effect transistor (“FET”). Beginning with FIG. 1, the semiconductor device 100 (e.g. a GaN-based semiconductor device) includes a substrate 105, which can include silicon, silicon carbide, sapphire, gallium nitride-based substrate or other suitable substrate material or substrate consisting of multiple materials. In examples where a silicon-based substrate is employed, the substrate 105 may have a seed layer (not expressly shown) deposited thereon. The seed layer (e.g., aluminum nitride) is necessary for the subsequent growth of a heterostructure, which, in the example shown here includes the to-be-formed channel layer and barrier layer. In examples where gallium-based substrate is employed, growing the heterostructure may not require the seed layer.

A channel layer 110 is formed over the substrate 105. The channel layer 110 may be, for example, 25 to 1000 nanometers of a III-nitride (“III-N”) material such as gallium nitride. The symbol “III” as used herein refers to elements in column 13 of the periodic table, and particularly to elements aluminum (“AI”), gallium (“Ga”) and indium (“In”). The channel layer 110 may be formed so as to reduce (e.g., minimize) crystal defects that may have an adverse effect on electron mobility. The method of formation of the channel layer 110 may result in the channel layer 110 being doped with carbon, iron, magnesium or other dopant species, for example, with a net doping density less than 10¹⁷ cm⁻³. The channel layer 110 is grown on the substrate 105 (or a seed layer over the substrate) using metal-organic chemical vapor deposition (MOCVD) or epitaxial (“epi”) growth using other suitable deposition processes.

Turning now to FIG. 2, a barrier layer 115 is formed over the channel layer 110. The barrier layer 115 includes a III-N material such as gallium nitride, with additional elements including aluminum and/or indium. III-N compounds that include each of In, Al, Ga and N may be referred to as quaternary compounds, those that include only three of these atomic species may be referred to as ternary compounds, and those that include two of these atomic species may be referred to as binary compounds. The barrier layer 115 may have a stoichiometry of In_{w}AlₓGa_{1-w-x}N, where w ranges from 0 to 30 percent, x ranges from 10 to 100 percent, and a thickness of 2 to 100 nanometers. In one version of the instant example, the barrier layer 115 may have a stoichiometry of Al_{0.25}Ga_{0.75}N with a thickness of 15 to 25 nanometers. A lower limit of the thickness of the barrier layer 115 may be selected to provide ease and reproducibility of fabrication; an upper limit of the thickness may be selected to provide a desired off-state current in the enhancement mode GaN FET, where increasing the thickness and/or Al composition of the barrier layer 115 increases the off-state current. A two-dimensional electron gas (“2DEG”) region 118 (designated by a dashed line) is generated between the channel layer 110 and the barrier layer 115. The barrier layer 115 is grown on the channel layer 110 using MOCVD or epitaxial growth.

Turning now to FIGS. 3 and 4, a cap layer 120 is formed over at least a portion of the barrier layer 115. The cap layer 120 includes a ternary or quaternary III-N material including as gallium and nitrogen, with additional elements including aluminum and/or indium. The cap layer 120 may have a stoichiometry of In_{y}Al_{z}Ga_{1-y-z}N, where y ranges from 5 to 30 percent and z ranges from 0 to 30 percent, and a thickness of 10 to 500 nanometers. In one version of the instant example, the cap layer 120 may have a stoichiometry of In_{0.1}Ga_{0.9}N with a thickness of 100 nanometers, which may provide a desired value of the threshold voltage. The cap layer 120 may also be doped with magnesium or other dopant species for +Ve threshold voltage assisting (enabling) the enhancement mode of operation. The cap layer 120 enables the GaN-based semiconductor device 100 to function in the enhancement mode as the presence of the cap layer 120 depletes the electrons present in the region 118 of the 2DEG under the cap layer 120. Due to this phenomenon, the GaN-based semiconductor device 100 is considered normally OFF. The cap layer 120 is grown on the barrier layer 115 using MOCVD or epitaxial growth. In order to define the cap layer 120 as illustrated in FIG. 4, a mask may be formed over the cap layer 120 so a chemical etchant can be used to remove the cap layer 120 in regions beyond a to-be-formed gate contact.

Turning now to FIG. 5, remaining device fabrication steps for source, gate and drain contacts are completed by mask and optional etch of the barrier layer 115 in order to expose the channel layer 110 in preparation to make contact to the region 118 of the two-dimensional electron gas (“2DEG”). A mask layer (not expressly shown) may be a dry film or a photoresist film covered on the surface to be etched through a suitable coating process, which may be followed by curing, descum, and the like, further followed by lithography technology and/or etching processes, such as a dry etch and/or a wet etch process, to form etched regions where the source and drain contacts are deposited.

Turning now to FIG. 6, metal layers are deposited to form the electrical contacts for the gate contact 125, source contact 130 and drain contact 135 thereby completing fabrication of the semiconductor device 100. The resulting GaN-based semiconductor device provides enhanced threshold voltage and reduced gate leakage current as compared to prior semiconductor devices such as p-doped gallium nitride (binary compound) (“p-GaN”)-based semiconductor devices.

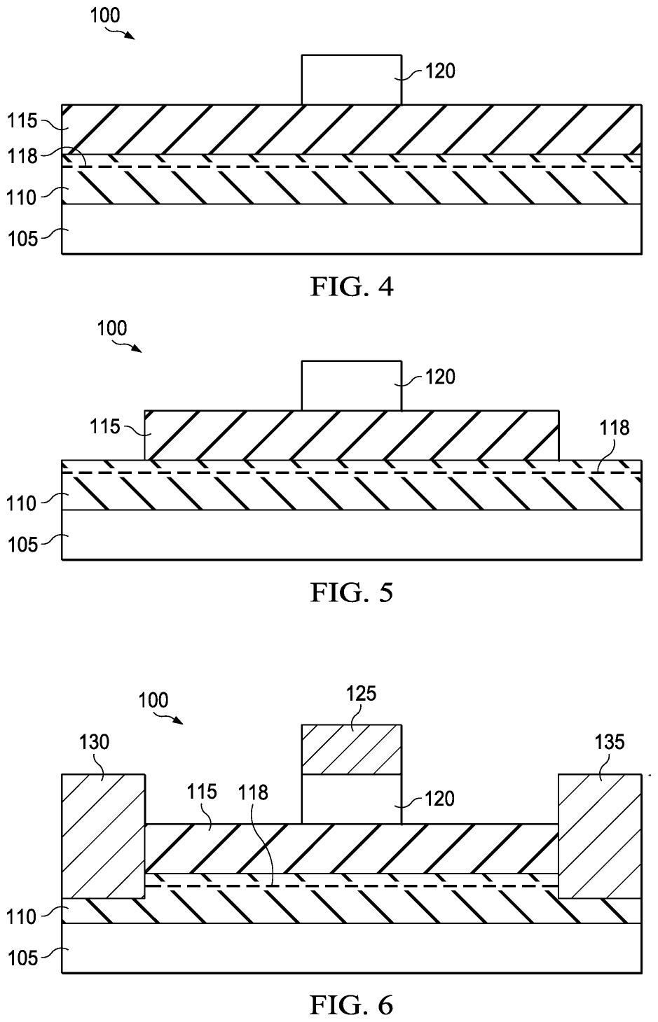

Turning now to FIGS. 7A to 7E, illustrated are block diagrams of example materials for a channel layer 710, barrier layer 720 and a cap layer 730 of a gallium nitride (“GaN”)-based semiconductor device. In each of FIGS. 7A-7E, the channel layer comprises GaN (binary compound). In FIG. 7A, the barrier layer 720 and cap layer 730 comprise indium aluminum gallium nitride (“InAlGaN”). In FIG. 7B, the barrier layer 720 comprises aluminum gallium nitride (“AlGaN”) and the cap layer 730 comprises indium aluminum gallium nitride (“InAlGaN”). In FIG. 7C, the barrier layer 720 comprises aluminum gallium nitride (“AlGaN”) and the cap layer 730 is indium gallium nitride (“InGaN”). In FIG. 7D, the barrier layer 720 comprises aluminum gallium nitride (“AlGaN”) and the cap layer 730 comprises p-doped indium gallium nitride e.g. doped with magnesium (“p-InGaN”). In FIG. 7E, the barrier layer 720 comprises indium aluminum nitride (“InAlN”) and the cap layer 730 comprises p-doped indium gallium nitride (“p-InGaN”). In general, the composition (e.g., materials and/or stoichiometry) and/or thickness of the barrier layer 720 and cap layer 730 may be different to control the threshold voltage and get leakage current of the GaN-based semiconductor device.

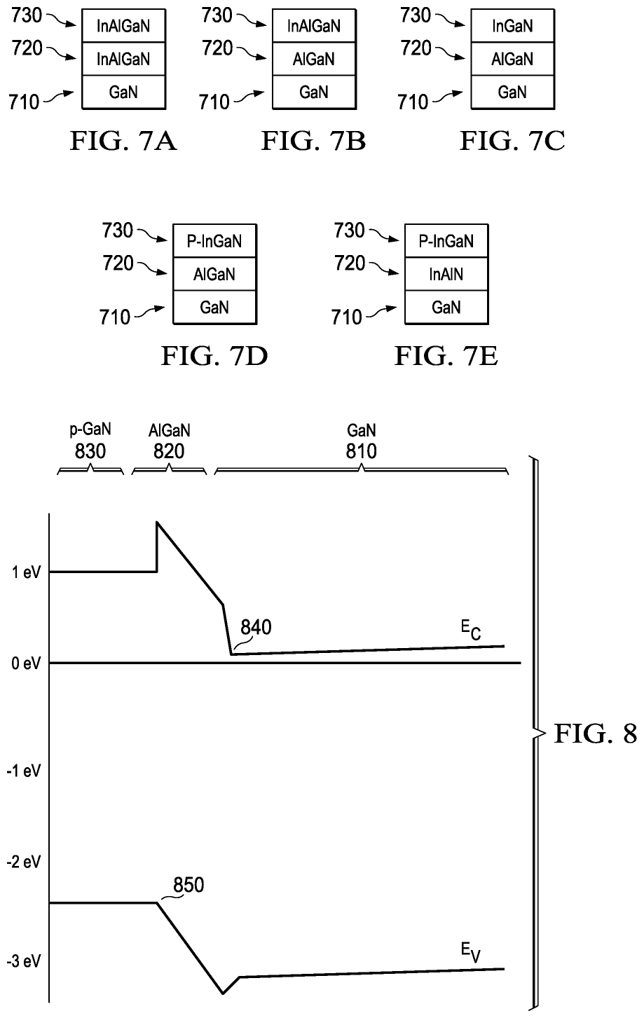

Turning now to FIG. 8, illustrated is an energy band diagram representative of a conventional p-doped gallium nitride (“p-GaN”)-based semiconductor device. (See, e.g., the '960 patent.) In this diagram, increasing distance from left to right represents increasing depth into the device through a p-GaN cap layer 830 (˜5 nm thick), an AlGaN barrier layer 820 and a GaN channel layer 810. The energy band diagram illustrates charge energy-band levels measured in units of electron-volts (“eV”) for electrons (conduction band, E_{c}) and for holes (valance band, Eᵥ). The interface between the AlGaN barrier layer 820 and p-GaN layer 830 exhibits a very low electron energy level 840 that is slightly above zero eV, which results in a threshold voltage substantially close to zero volts. As a result, the enhancement mode p-GaN-based semiconductor device has a weak threshold voltage (e.g. about zero volts) that does not offer strong immunity to external disturbances such as a noisy signal that could cause erroneous turn-on of the device. Furthermore, the lack of any hole barrier at 850 in the valence band energy indicates that holes may be relatively easily mobilized, leading to excess gate leakage.

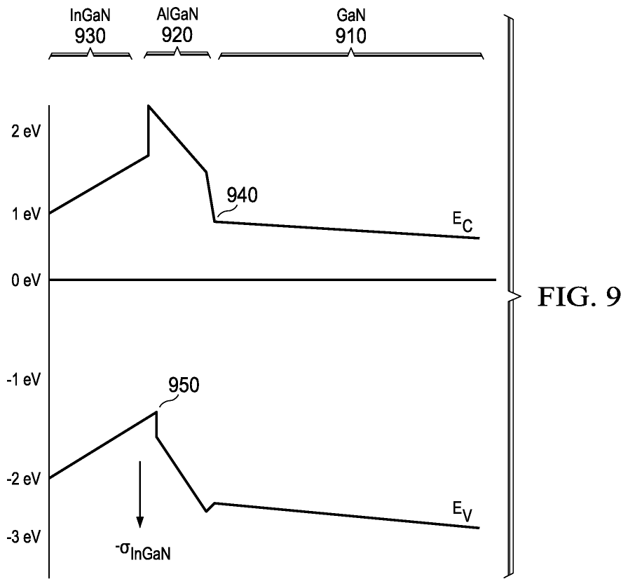

Turning now to FIG. 9, similar in form to FIG. 8, illustrated is an energy band diagram for a gallium nitride (“GaN”)-based semiconductor device as described by various examples herein. In this diagram, increasing distance from left to right represents increasing depth into the device through an In_{0.1}Ga_{0.9}N cap layer 930 (˜5 nm thick), an AlGaN barrier layer 920 and a GaN channel layer 910.

This GaN-based semiconductor device exhibits an increased electron energy level 940 at the interface between the GaN channel layer 910 and the AlGaN barrier layer 920 relative to the energy level 840 of FIG. 8. This results in a threshold voltage substantially higher than zero volts. As a result, the enhancement mode device has a strong positive threshold voltage. This is a desirable characteristic because it provides substantial protection to external disturbances such as noisy signals that could cause erroneous turn-on of the device. Additionally, the hole energy level 950 provides a reduction in mobile hole injection, thereby reducing gate leakage. Due to the excess induced negative polarization charge (designated “−σInGaN”) provided by spontaneous and piezoelectric polarization of InGaN, the energy band at the AlGaN barrier interface is lifted at the interface between the InGaN cap layer 930 and the AlGaN barrier layer 920. This means that holes injected from the gate electrode encounter a higher valence band energy barrier which in turn reduces leakage currents in the gate relative to the example of FIG. 8, which is a very desirable characteristic for such semiconductor devices. Thus, the negative polarization charge gives independent knob to improve threshold voltage margin without trading off with other performance metrics (e.g. Rdson or gate current leakage).

Thus, as introduced herein and with continuing reference to representative reference numbers, a semiconductor device (100), and related method of forming the same, includes a channel layer (110) including gallium nitride (“GaN”), and a barrier layer (115) of a first III-N material over the channel layer (110). The semiconductor device (100) also includes a cap layer (120) of a second III-N material including indium over the barrier layer (115) having the effect of modifying a threshold voltage and gate leakage current of the semiconductor device.

The first III-N material and the second III-N material are each a ternary or quaternary compound including gallium and nitrogen. The first III-N material of the barrier layer (115) and second III-N material of the cap layer (120) may include aluminum gallium nitride (“AlGaN”). The barrier layer (115) may have a stoichiometry of In_{w}AlₓGa_{1-w-x}N, where w ranges from 0 to 30 percent and x ranges from 10 to 100 percent. The cap layer (120) may have a stoichiometry of In_{y}Al_{z}Ga_{1-y-z}N, where y ranges from 5 to 30 percent and z ranges from 0 to 30 percent. A composition and thickness of the first III-N layer and the second III-N layer are different.

The cap layer (120) may be doped with magnesium or other dopant species to further enable an enhancement mode of operation. The cap layer (120) may include P-doped InGaN. The barrier layer (115) and the cap layer (120) may include InAlGaN. The barrier layer (115) may be free of indium and the cap layer (120) may include InAlGaN. The barrier layer (115) may include AlGaN and the cap layer (120) may include InGaN. The barrier layer (115) and the cap layer (120) may each include a quaternary compound. The barrier layer (115) and the cap layer (120 may each include a ternary compound. The barrier layer (115) may be free of gallium and the cap layer (120) may be free of aluminum. The barrier layer (115) may be free of indium and the cap layer (120) may be free of aluminum.

The semiconductor device (100) also includes a gate contact (125) formed over the cap layer (120) a source contact (130) extending through the barrier layer (115) to the channel layer (110), and a drain contact (135) extending through the barrier layer (115) to the channel layer (110).

Thus, a GaN-based semiconductor device, and related method of forming the same, has been introduced. It should be understood that the previously described examples of the semiconductor device, and related methods, are submitted for illustrative purposes only and that other examples capable of controlling threshold voltage and gate leakage current are well within the broad scope of the present disclosure.

Although the present disclosure has been described in detail, various changes, substitutions and alterations may be made without departing from the spirit and scope of the disclosure in its broadest form.

Moreover, the scope of the present application is not intended to be limited to the particular examples of the process, machine, manufacture, composition of matter, means, methods and steps described in the specification. The processes, machines, manufacture, compositions of matter, means, methods, or steps, presently existing or later to be developed, that perform substantially the same function or achieve substantially the same result as the corresponding examples described herein may be utilized according to the present disclosure. Accordingly, the appended claims are intended to include within their scope such processes, machines, manufacture, compositions of matter, means, methods, or steps.

What is claimed:

1. A semiconductor device, comprising:
a channel layer comprising gallium nitride (GaN);
a barrier layer of a first III-N material over the channel layer; and
a cap layer of a second III-N material comprising indium (In) over the barrier layer.

2. The semiconductor device as recited in claim 1 wherein the first III-N material and the second III-N material are each a ternary or quaternary compound comprising gallium and nitrogen.

3. The semiconductor device as recited in claim 1 wherein the first III-N material of the barrier layer and second III-N material of the cap layer comprises aluminum gallium nitride (AlGaN).

4. The semiconductor device as recited in claim 1 wherein the barrier layer has a stoichiometry of In_{w}AlₓGa_{1-w-x}N, where w ranges from 0 to 30 percent and x ranges from 10 to 100 percent.

5. The semiconductor device as recited in claim 1 wherein the cap layer has a stoichiometry of In_{y}Al_{z}Ga_{1-y-z}N, where y ranges from 5 to 30 percent and z ranges from 0 to 30 percent.

6. The semiconductor device as recited in claim 1 wherein a composition and thickness of the first III-N layer and the second III-N layer are different.

7. The semiconductor device as recited in claim 1 wherein the cap layer is doped with magnesium.

8. The semiconductor device as recited in claim 1 wherein the cap layer comprises P-doped InGaN.

9. The semiconductor device as recited in claim 1 wherein the barrier layer and the cap layer both comprise InAlGaN.

10. The semiconductor device as recited in claim 1 wherein the barrier layer is free of indium and the cap layer comprises InAlGaN.

11. The semiconductor device as recited in claim 1 wherein the barrier layer comprises AlGaN and the cap layer comprises InGaN.

12. The semiconductor device as recited in claim 1 wherein the barrier layer and the cap layer each comprise a quaternary compound.

13. The semiconductor device as recited in claim 1 wherein the barrier layer and the cap layer each comprise a ternary compound.

14. The semiconductor device as recited in claim 1 wherein the barrier layer is free of gallium and the cap layer is free of aluminum.

15. The semiconductor device as recited in claim 1 wherein the barrier layer is free of indium and the cap layer is free of aluminum.

16. A method of forming a semiconductor device, comprising:
forming a channel layer comprising gallium nitride (GaN) over a substrate;
forming a barrier layer of a first III-N material over the channel layer; and
forming a cap layer of a second III-N material comprising indium (In) over the barrier layer.

17. The method as recited in claim 16 wherein the first III-N material and the second III-N material are each a ternary or quaternary compound comprising gallium and nitrogen.

18. The method as recited in claim 16 wherein the first III-N material of the barrier layer and second III-N material of the cap layer comprises aluminum gallium nitride (AlGaN).

19. The method as recited in claim 16 wherein the barrier layer has a stoichiometry of In_{w}AlₓGa_{1-w-x}N, where w ranges from 0 to 30 percent and x ranges from 10 to 100 percent.

20. The method as recited in claim 16 wherein the cap layer has a stoichiometry of In_{y}Al_{z}Ga_{1-y-z}N, where y ranges from 5 to 30 percent and z ranges from 0 to 30 percent.
